(19) United States
(12) Patent Application Publication
(10) Pub. No.: US 2003/0139044 A1
(43) Pub. Date: Jul. 24, 2003

(54) Moving apparatus and control method therefor, and device manufacturing method

(75) Inventor: Hiroaki Takeishi, Tochigi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/340,684

(22) Filed: Jan. 13, 2003

(30) Foreign Application Priority Data
Jan. 16, 2002 (JP) 2002-007981

(51) Int. Cl. H01L 21/302

(52) U.S. Cl. 438/689; 438/690

(57) ABSTRACT

A moving apparatus according to this invention absorbs a reaction force generated upon driving a movable portion (3) by actuators (8, 8′) which has movable elements (2, 2′) and stators (1, 1′) by moving the left and right stators (1, 1′). The actuators (8, 8′) are controlled such that the moving distance of the movable portion (3) and that of the stators (1, 1′) have a predetermined relationship. With this operation, a moving apparatus which can move at high precision without transmitting vibrations to the outside in driving a stage, and an exposure apparatus using the same can be provided.

### FIELD OF THE INVENTION

The present invention relates to a moving apparatus and control method therefor, and a device manufacturing method.

### BACKGROUND OF THE INVENTION

In recent years, demands for higher-precision control have been increasing in moving apparatuses which move a substrate, component, structure, and other objects while mounting them on a stage. For example, along with an increase in integration degree of a semiconductor device, higher-precision micropatterning techniques are sought for in an exposure apparatus used for the manufacture of a semiconductor device and the like. To realize this, high-precision control of a moving apparatus such as a wafer stage and the like is required.

Typical exposure apparatuses used for the manufacture of semiconductor devices are a step & repeat exposure apparatus (also called a stepper) and a step & scan exposure apparatus (also called a scanner).

A stepper is an exposure apparatus for sequentially exposing, through a projection optical system, a plurality of exposure regions on a substrate with the pattern of a master (e.g., a reticle or mask) while stepping the substrate (e.g., a wafer or glass substrate) used for the manufacture of semiconductor devices.

A scanner is an exposure apparatus for repeating step movement and scanning exposure to repetitively perform exposure and transfer for a plurality of regions on a substrate.

This scanner uses only a light component relatively close to the optical axis of a projection optical system by restricting exposure light through a slit. Accordingly, the scanner enables higher-precision exposure of a fine pattern with a larger field.

These exposure apparatuses comprise stages (wafer stage and reticle stage) for moving a wafer and reticle at high speed. When an exposure apparatus drives a stage, the acceleration/deceleration of the stage entails generation of the reaction force of an inertial force. Transmission of this reaction force to a stage surface plate causes swings and vibrations of the stage surface plate. Consequently, natural vibrations are induced in the mechanism of an exposure apparatus, and high-frequency vibrations occur. Such vibrations interfere with high-precision control of a moving apparatus.

To reduce vibrations of the apparatus due to a reaction force, several proposals have been made. For example, in a moving apparatus described in Japanese Patent Laid-Open No. 5-77126, the stator of a linear motor used to drive a stage is supported on a floor provided independently of a stage surface plate, thereby avoiding swings of the stage surface plate due to a reaction force.

In a moving apparatus described in Japanese Patent Laid-Open No. 5-121294, an actuator applies a compensation force, which is equivalent to a reaction force generated upon stage driving, to a force generated in the horizontal direction for a machine frame which supports a wafer stage and projection lens, thereby reducing swings of the apparatus due to the reaction force.

In a conventional moving apparatus, however, even when swings of a moving apparatus can be reduced, a reaction force generated in stage driving is transmitted to a floor directly or through a member substantially integrated with the floor. The reaction force transmitted from the moving apparatus vibrates the floor, which in turn causes devices placed around the moving apparatus to vibrate. Accordingly, a conventional moving apparatus may adversely affect the devices placed around the moving apparatus.

Generally, the floor of an area on which a moving apparatus is placed has a natural frequency of 20 to 40 Hz. When natural vibrations are induced as the moving apparatus operates, an adverse effect is produced on the peripheral devices.

Vibrations can be suppressed to some extent by, e.g., increasing the rigidity of a floor as a countermeasure against this adverse effect. However, this operation requires the construction cost of a building in which the moving apparatus is placed. Additionally, in, e.g., a semiconductor manufacturing process, as the wafer size becomes large, the processing time per wafer is increasingly shortening, and the stage speed is trending upward. Along with this, the reaction force in stage driving is more and more increasing.

Hence, there is a need for a moving apparatus which can realize high-precision movement without transmitting vibrations from the moving apparatus to the outside, instead of suppressing vibrations owing to a building in which the moving apparatus is placed.

### SUMMARY OF THE INVENTION

The present invention has been made in consideration of the above problems, and has as its object to provide a moving apparatus which can move at high precision without transmitting vibrations to the outside, and an exposure apparatus using the same.

According to a first aspect of the present invention, there is provided a moving apparatus comprising a movable portion, a first actuator having a movable element which moves with the movable portion and a stator which can move, a second actuator which drives the stator, and a controller which controls the second actuator upon driving the movable portion by the first actuator such that a moving distance of the movable portion and a moving distance of the stator have a predetermined relationship.

According to a preferred embodiment of the present invention, the controller preferably performs feedback control such that the moving distance of the movable portion and the moving distance of the stator have the predetermined relationship.

According to a preferred embodiment of the present invention, preferably, the predetermined relationship is separately defined for each of a plurality of stators.

According to a preferred embodiment of the present invention, the predetermined relationship is preferably defined in accordance with a ratio between a mass of the movable portion and a mass of the stator.

According to a preferred embodiment of the present invention, the predetermined relationship dynamically changes in accordance with state quantities of the stator and the movable portion.

According to a preferred embodiment of the present invention, the predetermined relationship is defined on the basis of a ratio between a function which indicates a dynamic characteristic of the first actuator and a function which indicates a dynamic characteristic of the second actuator.

According to a second aspect of the present invention, there is provided an exposure apparatus comprising the above moving apparatus.

According to a third aspect of the present invention, there is provided a method of controlling a moving apparatus comprising a movable portion, a first actuator having a movable element which moves with the movable portion and a stator which can move, and a second actuator which drives the stator, comprising the step of controlling the second actuator such that a moving distance of the movable portion and a moving distance of the stator have a predetermined relationship.

According to a fourth aspect of the present invention, there is provided a semiconductor device manufacturing method comprising the step of forming a circuit on a substrate using the above exposure apparatus.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1A is a plan view of a moving apparatus;

FIG. 1B is a sectional view of the moving apparatus;

FIG. 2 is a schematic view for explaining the driving of the moving apparatus according to a preferred embodiment of the present invention;

FIG. 3 is a block diagram showing the feedback control system of the moving apparatus according to the preferred embodiment of the present invention;

FIG. 4 is a block diagram showing the feedback control system of a moving apparatus according to a more preferred embodiment of the present invention;

FIG. 5 is a block diagram showing the feedback control system of a moving apparatus according to a more preferred embodiment of the present invention;

FIG. 6A is a plan view of a moving apparatus according to another preferred embodiment of the present invention;

FIG. 6B is a sectional view of the moving apparatus according to the embodiment shown in FIG. 6A;

FIG. 7 is a view showing the concept of an exposure apparatus used when a moving apparatus according to the present invention is applied to a semiconductor device manufacturing process;

FIG. 8 is a flow chart showing the flow of the whole manufacturing process of a semiconductor device; and

FIG. 9 is a flow chart showing the detailed flow of a wafer process.

### DETAILED DESCRIPTION OF THE PREFERRED EMBODIMENTS

A moving apparatus and an exposure apparatus using the moving apparatus according to preferred embodiments of the present invention will be explained below with reference to the accompanying drawings. Note that the specific contents described in these embodiments are merely intended to help understanding the present invention, and the scope of the present invention is not limited to these. The same reference numerals denote the same parts throughout the drawings.

A moving apparatus according to a preferred embodiment comprises a movable portion 3, movable elements 2 and 2′ which move with the movable portion 3, and movable stators 1 and 1′. The moving apparatus according to the preferred embodiment of the present invention controls to drive the movable portion 3 such that the moving distance of the movable portion 3 and that of the stators 1 and 1′ have a predetermined relationship. Consequently, in the moving apparatus according to the preferred embodiment of the present invention, no vibrations are transmitted from the moving apparatus to the outside (e.g., a floor and other devices) in driving the movable portion 3, and the movable portion 3 can move at high precision.

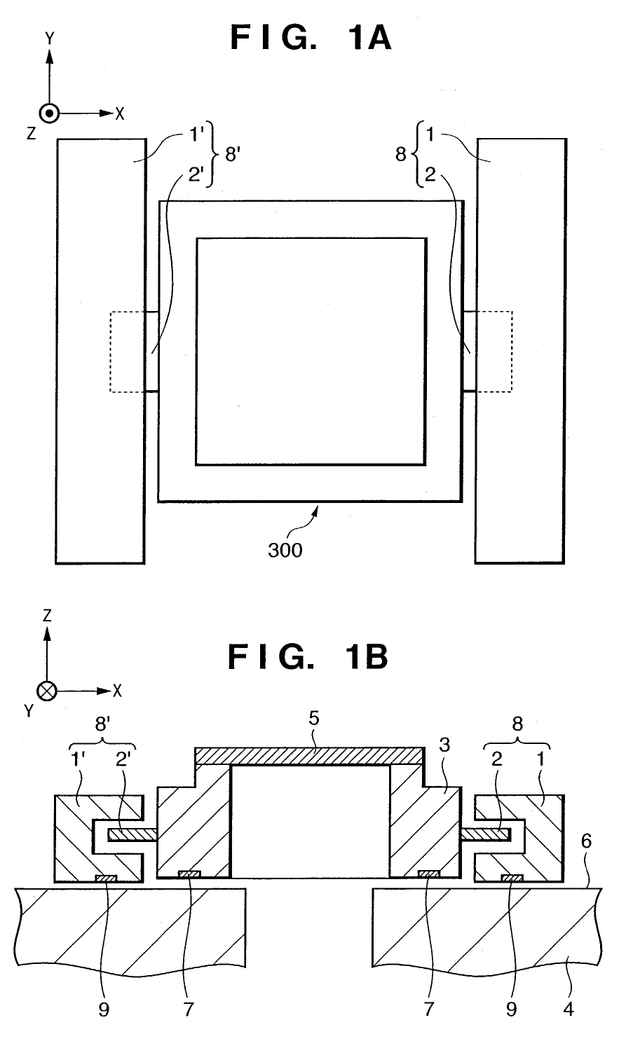

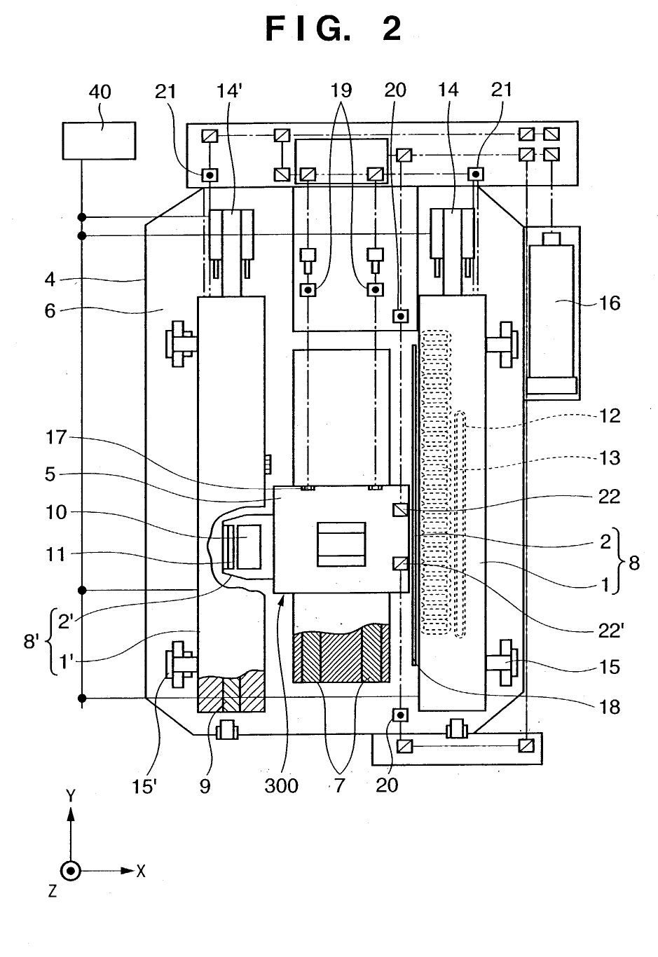

The arrangement of the moving apparatus according to the preferred embodiment of the present invention will be described with reference to FIGS. 1 and 2. Firstly, the principle of cancellation of a reaction force generated when a movable member moves will be explained with reference to FIG. 1. In FIGS. 1A and 1B, FIG. 1A is a plan view showing the arrangement of the moving apparatus, and FIG. 1B is a sectional view of the moving apparatus. As shown in FIG. 1B, a flat guide surface 6 serving as the reference plane of the moving apparatus is arranged on a reference structure 4. The movable portion 3 is supported in non-contact to the flat guide surface 6 by a hydrostatic bearing 7. The movable portion 3 can move in the Y direction along the flat guide surface 6. Electromagnetic actuators 8 and 8′ are provided on the two sides of the movable portion 3 to drive the movable portion 3 in the Y direction. The movable portion 3 is driven by these two electromagnetic actuators 8 and 8′. The electromagnetic actuators 8 and 8′ are respectively comprised of the movable elements 2 and 2′ connected to the movable portion 3, which moves along the flat guide surface 6, and the stators 1 and 1′. The left and right stators 1 and 1′ are supported in non-contact to the flat guide surface 6 by a hydrostatic bearing 9 and can move in the Y direction. The stators 1 and 1′ each have a predetermined mass and a function of absorbing a reaction force generated due to acceleration/deceleration of the movable portion 3. A top plate 5 or the like is provided on the movable portion 3. On the top plate 5, an object to be moved (e.g., a wafer) can be placed. In this embodiment, the stators 1 and 1′ are respectively constituted by permanent magnets, and the movable elements 2 and 2′ are respectively constituted by coils. However, the stators l.and 1′ may be constituted by coils, and the movable elements 2 and 2′ may be constituted by permanent magnets. Since one or a plurality of interferometers (not shown) are provided to control the moving apparatus, the movable elements 2 and 2′ or the movable portions 3 and 3′ can be positioned using the reference structure 4 as a reference. Similarly, the positions of the stators 1 and 1′, which move within a plane, can be measured by the interferometers (not shown) to position the stators 1 and 1′.

The left and right stators 1 and 1′ receive the reaction force of a force which acts when a movable member 300 including the movable portion 3 (including the top plate 5) and movable elements 2 and 2′ moves. Upon receipt of this reaction force, the left and right stators 1 and 1′ move along the flat guide surface 6. With the movement along the flat guide surface 6, the left and right stators 1 and 1′ absorb a reaction force generated upon driving the movable member 300. For example, if the movable member 300 including the movable portion 3 and the like is driven in the +Y direction, the left and right stators 1 and 1′ receive a reaction force in the −Y direction. The stators 1 and 1′ then move in the −Y direction, thereby absorbing the reaction force.

More specifically, the stators 1 and 1′ receive a reaction force at the time of acceleration/deceleration, which acts when the movable member 300 including the movable portion 3 moves. Upon receipt of the reaction force, the stators 1 and 1′ (reaction force movable portions) move, thereby converting this reaction force into kinetic energy. Although two stators are used here, the number of stators to be used may be, e.g., one, or three or more.

With the above arrangement, since a force which acts on the movable member 300 and its reaction force are limited to the flat guide surface 6, vibrations of the reference structure 4 which may be caused by a driving force which acts on the movable member 300, and a reaction force which acts on the stators 1 and 1′ can be avoided. In addition, the arrangement can eliminate transmission of vibrations to other apparatuses or the floor of an area in which the apparatus is placed.

The moving range of the stators 1 and 1′ can be narrowed by making the mass of the stators 1 and 1′ sufficiently larger than that of the movable member 300 including the movable portion 3. This realizes a reduction in size of the apparatus. For example, the floor area of a semiconductor factory can be reduced, thereby reducing the construction cost of the whole semiconductor factory.

Next, a more specific arrangement of the moving apparatus according to the preferred embodiment of the present invention will be explained. FIG. 2 shows the arrangement of the moving apparatus according to the preferred embodiment of the present invention. As shown in FIG. 2, the flat guide surface 6 serving as the reference plane of the moving apparatus is arranged on the reference structure 4. The movable portion 3 (not shown) is supported in non-contact to the flat guide surface 6 by the hydrostatic bearing 7 and can move in the X and Y directions. The top plate 5 (X-Y stage) is attached on the movable portion 3. The electromagnetic actuators 8 and 8′ are provided on the two sides of the movable portion 3 to drive the movable portion 3 with a long stroke in the Y direction and a short stroke in the X direction. The electromagnetic actuators 8 and 8′ have the movable elements 2 and 2′, which are separated from each other to the left and right, and the stators 1 and 1′. Two left and right Y magnets of the movable portion, and two left and right X magnets of the movable portion are attached to the left and right movable elements 2 and 2′. The left and right stators 1 and 1′ are supported in non-contact to the flat guide surface 6 by the hydrostatic bearing 9 and can move in the X and Y directions (plane direction). The stators 1 and 1′ each have a predetermined mass and their movement absorbs a reaction force generated upon acceleration/deceleration of the movable member 300 including the movable portion 3 and movable elements 2 and 2′. An X-axis linear motor single-phase coil 12 and a Y-axis linear motor polyphase coil 13 having a plurality of coils arrayed in the Y direction are arranged inside the left and right stators 1 and 1′. Movement in the X- and Y-axis directions is performed by switching between these coils 12 and 13.

The position of the top plate 5 (X-Y stage) is measured by a laser interferometer comprised of a laser head 16, a Y-axis measurement mirror 17, an X-axis measurement bar mirror 18, two left and right Y-axis measurement detectors 19, two front and rear X-axis measurement detectors 20, and the like. More specifically, optical elements 22 and 22′ which are mounted on the top plate 5 are irradiated with laser light in the Y direction, and their measurement light beams are reflected or polarized in the X-axis direction to irradiate the X-axis measurement bar mirror 18, so that the X-axis position of the top plate 5 is measured by the X-axis measurement detector 20. The Y-axis position of the top plate 5 is measured by the X-axis measurement detector 19 using laser light with which the Y-axis measurement mirror 17 is irradiated in the Y direction. The Y-axis positions of the stators 1 and l′ are measured by two left and right Y-axis measurement detectors 21.

The movable portion 3 having a master (reticle) or substrate (wafer) mounted on the top plate 5 (X-Y stage) moves in the X and Y directions by the electromagnetic actuators 8 and 8′ respectively comprised of the movable elements 2 and 2′ and the left and right stators 1 and 1′. The left and right stators 1 and 1′ receive the reaction force of a force which acts on the movable member 300 including the movable portion 3 and movable elements 2 and 2′. Upon receipt of this reaction force, the left and right stators 1 and 1′ move on the flat guide surface 6. The left and right stators 1 and 1′ move on the flat guide surface 6, thereby absorbing the reaction force. In this embodiment, for example, if the movable member 300 including the movable portion 3 moves in the +Y direction, the left and right stators 1 and 1′ receive a reaction force in the −Y direction and move in the −Y direction. The effect obtained by absorbing the reaction force has been described above.

Additionally, in this embodiment, two left and right Y-axis position control linear motors 14 and 14′ are provided on the reference structure 4 as actuators which drive the stators 1 and 1′ in the Y-axis direction. Similarly, four right, left, front, and rear X-axis position control linear motors 15 and 15′ which can drive the stators 1 and 1′ in the X-axis direction are provided on the reference structure 4.

Assume that the movable portion 3 having the top plate 5 mounted thereon is driven in the Y direction by the electromagnetic actuators 8 and 8′ comprised of the movable elements 2 and 2′ and left and right stators 1 and 1′. In this case, feedback control operation is performed for the electromagnetic actuators 8 and 8′ comprised of the movable elements 2 and 2′ and left and right stators 1 and 1′, using the position information of the movable portion 3 measured by the Y-axis measurement detector 19, thereby positioning the movable portion 3.

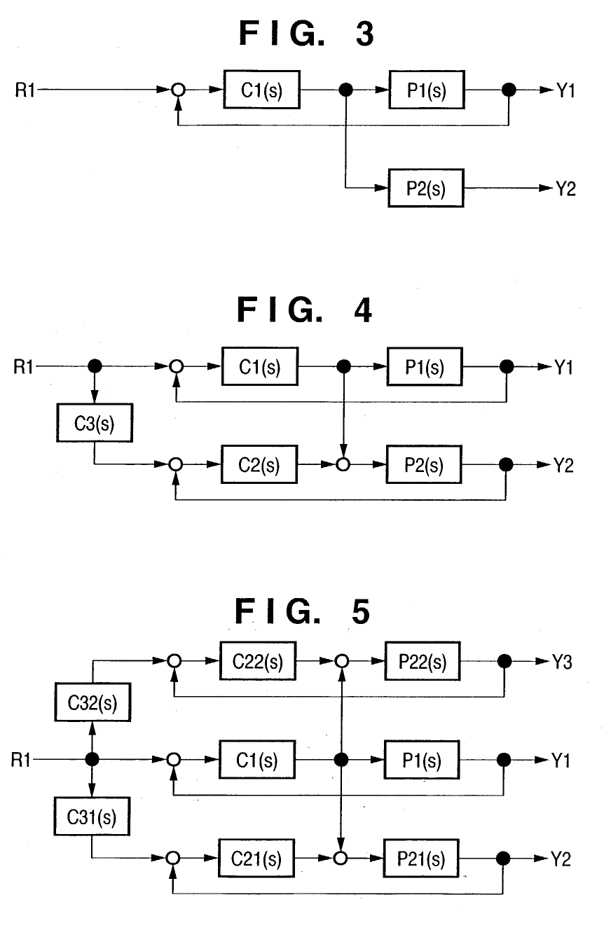

More specifically, a controller 40 controls the electromagnetic actuators 8 and 8′ on the basis of the measurement result (actual position in the Y direction) by the Y-axis measurement detector 19 such that the movable portion 3 reach a target position. When the controller 40 moves the movable member 300 including the movable portion 3, it controls the Y-axis position control linear motors 14 and 14′ on the basis of the target position of the movable portion 3 to absorb a reaction force received by the stators 1 and 1′. This feedback control operation will be explained in detail with reference to FIG. 3.

FIG. 3 is a block diagram showing the feedback control system in the movable portion of the moving apparatus according to the preferred embodiment of the present invention. In FIG. 3, P1(s) represents the dynamic characteristic of the electromagnetic actuators 8 and 8′ comprised of the movable elements 2 and 2′ and the left and right stators 1 and 1′. P2(s) represents the dynamic characteristic of a system comprised of the Y-axis position control linear motors 14 and 14′ and the left and right stators 1 and 1′. The dynamic characteristics P1(s) and P2(s) output measurement positions Y1 and Y2, respectively. Y1 represents the measurement position of the movable portion 3 measured by the Y-axis measurement detector 19. Y2 represents the measurement position of the stators 1 and 1′ measured by the Y-axis measurement detectors 21.

This feedback control system is controlled by the controller 40 of FIG. 2. The controller 40 typically includes a compensator C1(s) which supplies manipulated variables. The compensator C1(s) has a function of supplying the dynamic characteristic P1(s) with a manipulated variable for driving the movable portion 3 to a predetermined position in accordance with a target value R1. In addition, the controller 40 controls the Y-axis position control linear motors 14 and 14′ in driving the movable portion 3 by the electromagnetic actuators 8 and 8′ such that the moving distance of the movable portion 3 and that of the stators 1 and 1′ has a predetermined relationship. In FIG. 3, a manipulated variable to the dynamic characteristic P1(s) is also input to the dynamic characteristic P2(s). This is because manipulated variables generated in the electromagnetic actuators 8 and 8′ correspond to a reaction force of the movable portion 3.

If the dynamic characteristic P2(s) is a complete linear factor, the measurement positions Y1 and Y2 are bound by the action-reaction law. Accordingly, a reaction force generated in driving the movable elements 2 and 2′ is effectively absorbed by movement of the stators 1 and 1′.

However, in some actual cases, the dynamic characteristic P2(s) is not a complete linear factor under the influence of, e.g., a nonlinear component of the hydrostatic bearing 9 provided on the flat guide surface 6, wiring or piping (not shown) for the stators 1 and 1′, and the like. A case wherein disturbance occurs is considered as the same case. In these cases, the effect of absorbing a reaction force by movement of the stators 1 and l′ decreases.

Under the circumstances, in a more preferred embodiment of the present invention to be described below, there is provided a feedback control system configured to further have a compensator C2(s) and control the positions of stators 1 and 1′ using a measurement position Y2 of the stators 1 and 1′.

FIG. 4 is a block diagram showing the feedback control system of the stators 1 and 1′ in the more preferred embodiment of the present invention.

In this feedback control system, the compensator C2(s), which uses the measurement position Y2 of the stators 1 and 1′ as a feedback signal, is further provided. In addition, a compensator C3(s) is provided to supply the target position of the feedback control system which controls the positions of the stators 1 and 1′.

This feedback control system controls a movable portion 3 and the stators 1 and 1′ such that the ratio between the moving distance of the movable portion 3 and that of the stators 1 and 1′ is a predetermined value. With this control, a reaction force generated when the movable portion 3 moves can more effectively be absorbed by movement of the stators 1 and 1′.

Note that a compensator C1(s) determines the position accuracy of the movable portion 3 and controls the exposure accuracy. For this reason, the compensator C1(s) desirably has a wide band. On the other hand, the compensator C2(s) determines the position accuracy of the stators 1 and 1′, which absorb a reaction force and thus need not have a wide band. It suffices if the control band of the compensator C2(s) is identical to or narrower than that of the compensator C1(s).

If a measurement position Yl and the measurement position Y2 are controlled at high precision using two feedback control subsystems, the characteristic of the compensator C3(s) can be set as follows:

C3(s)=P2(s)/P1(s)

With this arrangement, electromagnetic actuators 8 and 8′ comprised of movable elements 2 and 2′ and the left and right stators 1 and 1′, and Y-axis position control linear motors 14 and 14′ can be controlled such that the ratio between the moving distance of the movable portion 3 and that of the stators 1 and 1′ corresponds to the ratio between the dynamic characteristic of the electromagnetic actuators 8 and 8′ and that of a system comprised of the Y-axis position control linear motors 14 and 14′ and left and right stators 1 and 1′. In this case., the manipulated variable for the dynamic characteristic P2(s) becomes substantially zero. This means that a reaction force generated in driving the movable portion 3 is effectively absorbed.

Generally, the dynamic characteristic P1(s) or P2(s) is configured like a double integrator for the electromagnetic actuators 8 and 8′. Since the gain of the compensator C3(s) is represented by the reciprocal of a mass, the simplest characteristic of the compensator C3(s) is represented by the ratio between the mass of the movable portion 3 and that of the stators 1 and 1′. If the target position for the control system of the stators 1 and 1′ is set to a value obtained by multiplying a target position R1 of the movable portion 3 by the mass ratio between the movable portion 3 and the stators 1 and 1′, a reaction force can effectively be absorbed.

However, the target position R1 may generally be multiplied by the characteristic of the compensator C3(s) comprising a dynamic characteristic, depending on the control purpose. For example, a value different from the mass ratio between the movable portion 3 and the stators 1 and 1′ may be set as the gain of the compensator C3(s) so as to minimize the manipulated variable of an actuator which controls the stators 1 and 1′. This can decrease a force generated in the Y-axis position control linear motors 14 and 14′ supporting a reference structure 4 and consequently can decrease a force to be applied to the reference structure 4. When a force is applied to the reference structure 4, the reference structure 4 may deform. Therefore, it is important to decrease such a force.

Assume that the characteristic of the compensator C3(s) is set to a medium value between a value determined so as to decrease a force to be applied to the reference structure 4, and a value determined on the basis of the mass ratio between the movable portion 3 and the stators 1 and 1′. In this case, a higher-precision control system with consideration for a trade-off between the two values can be realized.

In a system having the two stators 1 and 1′ arranged independently of each other, as shown in FIG. 2, if the two stators 1 and 1′ are different in mass and characteristic, an effect which is the same as or better than the above-described effect can be obtained by separately setting the characteristic of the compensator C3(s) for each of the two stators 1 and 1′.

FIG. 5 is a block diagram showing the feedback control systems which independently control two stators in a moving apparatus according to a preferred embodiment of the present invention.

FIG. 5 shows characteristics P21(s) and P22(s) of two stators 1 and 1′, characteristics C21(s) and C22(s) of a compensator for controlling these stators 1 and 1′, and characteristics C31(s) and C32(s) by which a target position R1 of a movable portion is multiplied to set the target values of the respective stators 1 and 1′. The principle of operation of this feedback control system is the same as that in FIG. 4. As described above, the stators 1 and 1′ can be controlled independently of each other by setting a feedback control subsystem for each of the stators 1 and 1′.

In addition, the characteristics C31(s) and C32(s) can dynamically be changed on the basis of the status quantities (positions) of a movable portion 3 and the stators 1 and 1′. In this case, the characteristics C31(s) and C32(s) can be set in accordance with the control purpose.

Likewise, when three or more stators are used, a feedback control subsystem can independently be set for each of the three or more stators.

As described above, use of the feedback control system enables effective absorption of a reaction force even if the characteristics P21(s) and P22(s) are not complete linear factors. Even when a plurality of stators are used, a reaction force can effectively be absorbed by setting a feedback control subsystem for each of the plurality of stators.

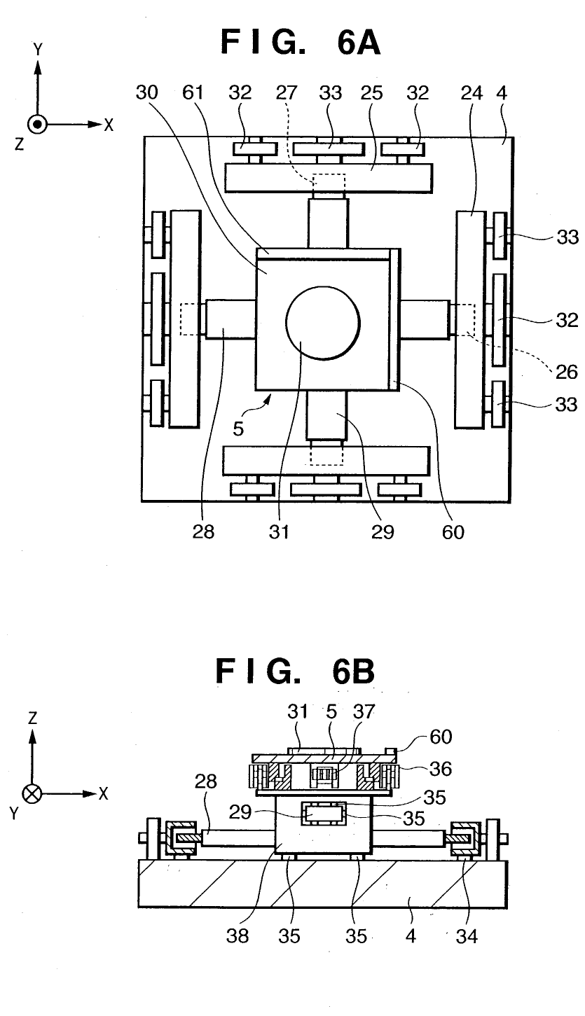

Next, a moving apparatus (six-axis movable stage) according to another preferred embodiment of the present invention will be explained with reference to FIGS. 6A and 6B.

In FIGS. 6A and 6B, a wafer chuck 30, and bar mirrors 60 and 61 are provided on a top plate 5. The wafer chuck 30 vacuum-chucks and holds a wafer 31 serving as an object to be positioned. The bar mirrors 60 and 61 reflect measurement light from a laser interferometer (not shown). The top plate 5 levitates in non-contact to an X-Y slider 38 by a light weight compensator (not shown) which uses a magnet and has six degrees of freedom in six axial directions. The top plate 5 is finely driven in six axial directions (X, Y, and Z directions and their rotational directions) by an actuator which generates a driving force between the top plate 5 and the X-Y slider 38. Two linear motors in the X direction, one linear motor in the Y direction, and three linear motors in the Z direction are provided as actuators for fine moving in six axial directions. If the two X-direction fine moving linear motors are driven in opposite directions, the top plate 5 can be driven about the Z-axis (θ direction). By adjusting the driving forces of the three Z-direction fine moving linear motors, the top plate 5 can be driven about the X-axis (ωX direction) and about the Y-axis (ωY direction). A coil serving as the stator of the fine moving linear motor is provided on the side of the X-Y slider 38, and a permanent magnet serving as the movable element of the fine moving linear motor is provided on the side of the top plate 5.

The X-Y slider 38 is guided by an X guide bar 28 and a Y guide bar 29 through air bearings (hydrostatic bearings) 35. The X-Y slider 38 is guided in the Z-axis direction on the upper surface of a reference structure 4 by the air bearings (hydrostatic bearings) 35.

Movable elements (magnets) 26 and 27 of linear motors are attached near the two ends of the X guide bar 28 and those of the Y guide bar 29. A Lorentz force is generated by flowing a current through two X linear motor stators and two Y linear motor stators (coils) 24 and 25, thereby driving the X guide bar 28 in the Y direction and the Y guide bar 29 in the X direction. The two X linear motor stators and two Y linear motor stators (coils) 24 and 25 are guided in the Z direction on the upper surface of the reference structure 4 by air bearings (hydrostatic bearings) 34 and have the degrees of freedom in the X and Y directions.

X-direction movement of the X-Y slider 38 will be explained. When the Y guide bar 29 is driven in the X direction by a Lorentz force, a force is applied to the X-Y slider 38 in the X direction through the hydrostatic bearings 35. A combination of the X-Y slider 38 and Y guide bar 29 will be referred to as an X movable portion hereinafter. When the X movable portion is accelerated/decelerated, a reaction force generated due to the acceleration/deceleration acts on the X linear motor stator 25. Since the X linear motor stator 25 is supported movably in the X and Y directions by the hydrostatic bearings 34, the reaction force moves the X linear motor stator 25 in the X direction. The acceleration and speed at the time of movement depends on the ratio between the mass of the X linear motor stator 25 and that of the X movable portion. For example, assume that the mass of the X linear motor stator 25 is 200 kg/piece, and the mass of the X movable portion is 40 kg. In this case, the mass ratio is 10:1, and accordingly the acceleration and speed of the X linear motor stator 25 are ideally 1/10those of the X movable portion. When the X linear motor stator 25 moves in the X direction in this manner, the reaction force in the X direction, which is applied to the X linear motor stator 25, is not ideally transmitted to the reference structure 4.

However, resistance, friction, and the like occur when the X linear motor stator 25 moves. Accordingly, the X linear motor stator 25 does not always move as intended.

Linear motors 33 for controlling a linear motor stator position, at least two in the X direction and one in the Y direction, are provided to drive the X linear motor stator 25 relative to the reference structure 4. The linear motor 33 for controlling a linear motor stator position drives such that the ratio between the moving distance of the X linear motor stator 25 and that of the X movable portion is a predetermined value.

More specifically, in this moving apparatus, the X linear motor stator 25 and X movable portion are controlled at high precision using a feedback control system as described with reference to FIGS. 4, 5, and the like such that the ratio between the moving distance of the X linear motor stator 25 and that of the X movable portion is a predetermined value.

Additionally, generation of a moment can be suppressed in the ωY direction by equating the Z level of the barycenter of the X movable portion and that of the generation point of force of the X linear motor movable element. This prevents a driving reaction force from transmitting to the reference structure 4. Similarly, generation of a moment can be suppressed in the ωY direction by equating the Z level of the generation point of force of the X linear motor movable element 22 and that of the barycenter of the X linear motor stator 25.

The above explanation about the X direction also applies to the Y direction.

According to this embodiment, since the X-Y slider 38 can move in the X and Y directions, the linear motor outputs different driving forces depending on the position of the X-Y slider 38. For example, assume that the X-Y slider 38 moves in the +Y direction and then in the +X direction in FIG. 6A. In this case, the X-Y slider 38 is leaning to the side of the +Y direction when the X-Y slider 38 moves in the +X direction. For this reason, a driving force output by the X linear motor stator 25 on the upper side of FIG. 6A is larger than a driving force output by the X linear motor stator 25 on the lower side. At this time, if the driving forces output by the two X linear motor stators 25 are equal to each other, it means that the X-Y slider 38 receives a moment in the l direction. If the stators are integrally connected to each other, a moment in the l direction may be applied to the X-Y slider 38 upon cancellation of a driving reaction force, depending on the position of the X-Y slider 38. In this embodiment, even if the linear motors output different driving forces, each linear motor stator, which is independently supported movably in the X and Y directions by the reference structure 4, can independently cancel a driving reaction force. In this embodiment as well, generation of vibrations due to a reaction force can be suppressed by performing high-precision control using the above-described feedback control system such that the ratio between the moving distance of the X linear motor stator 25 and that of the X movable portion is a predetermined value.

As described above, according to the preferred embodiment of the present invention, the stator receives a reaction force at the time of movement (acceleration/deceleration) of the movable portion and moves, thereby converting/absorbing the reaction force into the kinetic energy of the stator. Control is performed such that the moving distance of the movable portion and that of the stator have a predetermined relationship, thereby effectively preventing the reference structure of the apparatus from being shaken due to a reaction force generated when driving the movable portion.

Additionally, since the two left and right stators (reaction force movable portions) move on the reference structure of the apparatus in accordance with the acceleration of the movable member, the unbalanced load at the time of movement of the movable member can be reduced.

According to an exposure apparatus of the present invention which has the above-described stage, firstly, higher precisions than the prior art, i.e., an increase in overlay accuracy, line width accuracy, throughput, and the like can be achieved by reducing the influence of vibrations and swings generated upon movement of the stage. Additionally, since the unbalanced load at the time of movement of the movable member can be reduced, an increase in overlay accuracy can be attained. Moreover, the influence on other devices placed on a floor can be reduced by reducing the influence, on the floor, of a reaction force generated upon acceleration/deceleration of the stage. Simultaneously, various effects, i.e., an effect of avoiding an increase in footprint on the floor, an effect of relaxing restrictions on the rigidity of the installation floor, and the like can be obtained.

Next, an embodiment will be explained in which a moving apparatus according to the present invention is applied to an exposure apparatus used in a semiconductor device manufacturing process.

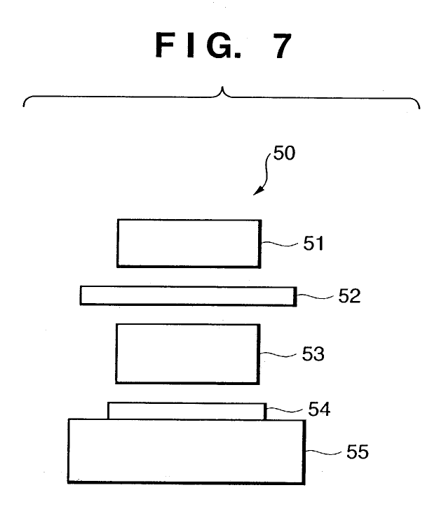

FIG. 7 shows the concept of the exposure apparatus used when the moving apparatus of the present invention is applied to the semiconductor device manufacturing process.

An exposure apparatus 50 according to a preferred embodiment of the present invention is comprised of an illumination optical system 51, a reticle 52, a projection optical system 53, a substrate 54, and a moving apparatus 55. The illumination optical system 51 can employ, as exposure light, e.g., ultraviolet rays which use an excimer laser, fluorine excimer laser, or the like as a light source. Light emitted from the illumination optical system 51 illuminates the reticle 52. The light having passed through the reticle 52 is focused on the substrate 54 through the projection optical system 53 to expose a photosensitive member applied on the substrate 54. The substrate 54 placed on a top plate 5 in FIGS. 1 and 2 moves to a predetermined position using the moving apparatus 55 of the present invention.

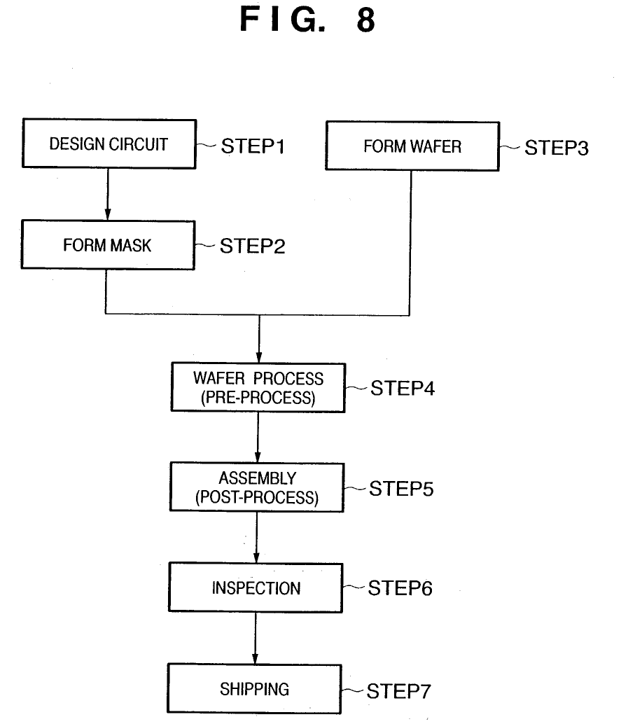

FIG. 8 shows the flow of the whole manufacturing process of a semiconductor device using the above-described exposure apparatus. In step 1 (circuit design), a semiconductor device circuit is designed. In step 2 (mask formation), a mask having the designed circuit pattern is formed. In step 3 (wafer formation), a wafer is formed by using a material such as silicon. In step 4 (wafer process) called a pre-process, an actual circuit is formed on the wafer by lithography using the prepared mask and wafer. Step 5 (assembly) called a post-process is the step of forming a semiconductor chip by using the wafer formed in step 4, and includes an assembly process (dicing and bonding) and packaging process (chip encapsulation). In step 6 (inspection), the semiconductor device manufactured in step 5 undergoes inspections such as an operation confirmation test and durability test. After these steps, the semiconductor device is completed and shipped (step 7).

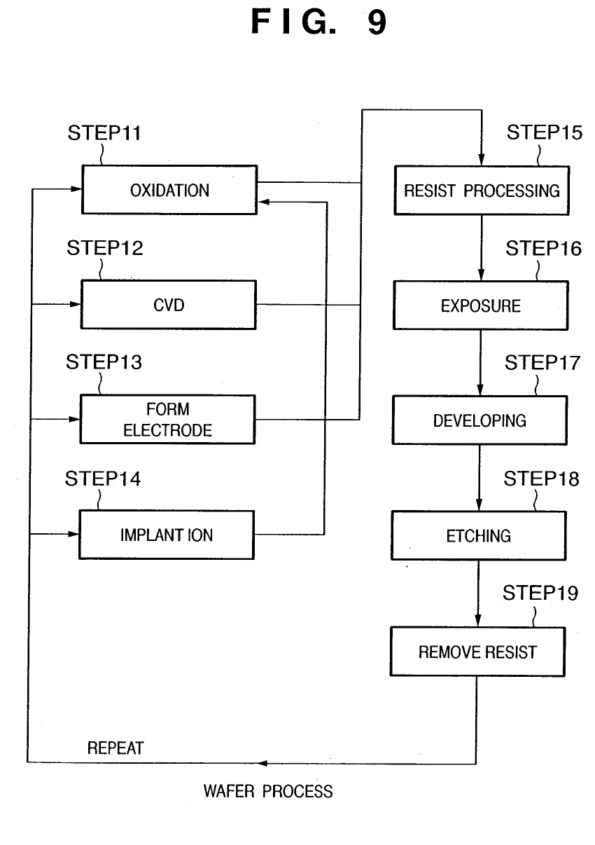

FIG. 9 shows the detailed flow of the wafer process. In step 11 (oxidation), the wafer surface is oxidized. In step 12 (CVD), an insulating film is formed on the wafer surface. In step 13 (electrode formation), an electrode is formed on the wafer by vapor deposition. In step 14 (ion implantation), ions are implanted in the wafer. In step 15 (resist processing), a photosensitive agent is applied to the wafer. In step 16 (exposure), the wafer is moved at high precision using the above-mentioned exposure apparatus, and the circuit pattern is transferred onto the wafer. In step 17 (developing), the exposed wafer is developed. In step 18 (etching), the resist is etched except for the developed resist image. In step 19 (resist removal), an unnecessary resist after etching is removed. These steps are repeated to form multiple circuit patterns on the wafer.

Use of the aforementioned process enables movement of a wafer at high precision and transfer of a circuit pattern on the wafer in the exposure process. Additionally, the wafer can be exposed without transmitting vibrations to other devices in the exposure step.

According to the present invention, for example, a moving apparatus which can move at high precision without transmitting vibrations to the outside, and an exposure apparatus using the same can be provided.

As many apparently widely different embodiments of the present invention can be made without departing from the spirit and scope thereof, it is to be understood that the invention is not limited to the specific embodiments thereof except as defined in the appended claims.

What is claimed is:

1. A moving apparatus comprising:
a movable portion;
a first actuator having a movable element which moves with said movable portion and a stator which can move;
a second actuator which drives the stator; and
a controller which controls said second actuator upon driving said movable portion by said first actuator such that a moving distance of said movable portion and a moving distance of the stator have a predetermined relationship.

2. The apparatus according to claim 1, wherein said controller performs feedback control such that the moving distance of said movable portion and the moving distance of the stator have the predetermined relationship.

3. The apparatus according to claim 1, wherein the predetermined relationship is separately defined for each of a plurality of stators.

4. The apparatus according to claim 1, wherein the predetermined relationship is defined in accordance with a ratio between a mass of said movable portion and a mass of the stator.

5. The apparatus according to claim 1, wherein the predetermined relationship dynamically changes in accordance with state quantities of the stator and said movable portion.

6. The apparatus according to claim 1, wherein the predetermined relationship is defined on the basis of a ratio between a function which indicates a dynamic characteristic of said first actuator and a function which indicates a dynamic characteristic of said second actuator.

7. An exposure apparatus comprising a moving apparatus according to claim 1.

8. A method of controlling a moving apparatus comprising a movable portion, a first actuator having a movable element which moves with the movable portion and a stator which can move, and a second actuator which drives the stator, comprising the step of
controlling the second actuator such that a moving distance of the movable portion and a moving distance of the stator have a predetermined relationship.

9. A semiconductor device manufacturing method comprising the step of forming a circuit on a substrate using an exposure apparatus according to claim 7.
